(19) United States
(12) Patent Application Publication
(10) Pub. No.: US 2025/0147433 A1
(43) Pub. Date: May 8, 2025

(54) FIELD OF VIEW SELECTION FOR METROLOGY ASSOCIATED WITH SEMICONDUCTOR MANUFACTURING

(71) Applicant: ASML NETHERLANDS B.V., Veldhoven (NL)

(72) Inventors: Tsung-Pao FANG, Milpitas, CA (US); Been-Der CHEN, Milpitas, CA (US); Wei-Yin LIN, San Jose, CA (US); Fei YAN, Shenzhen (CN); Meng LIU, Shenzhen (CN); Rencheng SUN, Shenzhen (CN)

(73) Assignee: ASML NETHERLANDS B.V., Veldhoven (NL)

(21) Appl. No.: 18/834,131

(22) PCT Filed: Jan. 31, 2023
(86) PCT No.: PCT/EP2023/052215

§ 371 Date: Jul. 29, 2024

(30) Foreign Application Priority Data
Feb. 21, 2022 (WO) PCT/CN2022/077061

(51) Int. Cl. G03F 7/00; G01N 23/2251

(52) U.S. Cl. CPC G03F 7/70655; G01N 23/2251; G03F 7/70491; G01N 2223/6116

(57) ABSTRACT

Selecting one or more lists of fields of view of a pattern layout for scanning electron microscope measurement and/or other inspection. A set of candidate fields of view is determined based on pattern groups of a pattern layout and a constraint on a characteristic of a given field of view. The characteristic of a given field of view includes a distance from the given field of view to another field of view and/or a size of the given field of view. The one or more lists are selected from the set of candidate fields of view according to prescribed criteria for combinations of fields of view included in the one or more lists. The prescribed criteria causes inclusion of an optimally diverse group of patterns in a predetermined number of lists of fields of view.

### CROSS-REFERENCE TO RELATED APPLICATIONS

This application claims priority of International application PCT/CN2022/077061 which was filed on Feb. 21, 2022 and which is incorporated herein in its entirety by reference.

### TECHNICAL FIELD

The present disclosure relates generally to field of view selection for metrology associated with semiconductor manufacturing.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction.

Different portions of the pattern on the patterning device are transferred to one target portion progressively. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced. At the same time, the number of functional elements, such as transistors, per device has been steadily increasing, following a trend commonly referred to as “Moore's law.” At the current state of technology, layers of devices are manufactured using lithographic projection apparatuses that project a design layout onto a substrate using illumination from an illumination source, creating individual functional elements having dimensions well below 100 nm.

This process in which features with dimensions smaller than the classical resolution limit of a lithographic projection apparatus are printed, is commonly known as low-k1 lithography, according to the resolution formula CD=k1×λ/NA, where λ is the wavelength of radiation employed (currently in most cases 248 nm or 193 nm), NA is the numerical aperture of projection optics in the lithographic projection apparatus, CD is the “critical dimension”-generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, source mask optimization (SMO), or other methods generally defined as “resolution enhancement techniques” (RET).

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, and their structures continue to become more complex, accuracy and throughput in defect detection and inspection become more important.

### SUMMARY

Users typically manually select fields of view for metrology and inspection that include various diverse patterns. Often, some of the fields of view overlap with each other, have pattern geometry that is only slightly different, and include a large amount of redundant information from one field of view to the next. The large number of groups, the redundant information, and/or other factors, can burden downstream computing (e.g., process monitoring, computational lithography, etc.) processes because the large number and/or redundant information creates a need for significant computing resources. Overlapping fields of view may cause wafer charging in scanning electron microscope (SEM) measurement. In addition, manual selection generally makes the manufacturing process less efficient and/or has other disadvantages.

According to an embodiment, there is provided a method for selecting one or more subsets of fields of view of a pattern layout. The method comprises determining a set of candidate fields of view based on pattern groups of the pattern layout, and selecting the one or more subsets of the fields of view from the set of candidate fields of view according to prescribed criteria. The prescribed criteria is for combinations of fields of view included in the one or more subsets for scanning electron microscope (SEM) measurement.

In some embodiments, the method comprises grouping patterns of the pattern layout into the pattern groups. The grouping comprises pattern matching to produce the pattern groups.

In some embodiments, each of the one or more subsets corresponds to a field of view list.

In some embodiments, a field of view includes a portion of the pattern layout.

In some embodiments, a subset of fields of view comprises a list of fields of view selected from the set of candidate fields of view.

In some embodiments, selecting the one or more subsets comprises assigning fields of view including specific patterns to respective fields of view lists by applying a graph based overlapping elimination algorithm.

In some embodiments, the graph based overlapping elimination algorithm comprises a graph coloring algorithm, and each field of view list corresponds to a color.

In some embodiments, the prescribed criteria is configured such that the graph based elimination and/or graph coloring algorithm outputs an optimally diverse group of patterns in a predetermined number of lists of fields of view.

In some embodiments, selecting the one or more subsets comprises assigning fields of view including specific patterns to respective fields of view lists by applying an integer linear programming algorithm.

In some embodiments, selecting the one or more subsets comprises assigning fields of view including specific patterns to respective fields of view lists by applying the integer linear programming algorithm and a graph coloring algorithm, wherein each field of view list corresponds to a color.

In some embodiments, the prescribed criteria is configured such that the integer linear programming and/or graph coloring algorithm outputs an optimally diverse group of patterns in a predetermined number of lists of fields of view.

In some embodiments, determining the set of candidate fields of view is further based constraints on characteristics of a given field of view.

In some embodiments, the characteristics of a given field of view comprise a distance from the given fields of view to another fields of view and/or a size of the given field of view.

In some embodiments, determining the set of candidate fields of view is further based on a generation method comprising matched instance pattern replacement for the set of candidate fields of view.

In some embodiments, the matched instance pattern replacement comprises pattern matching of patterns in the pattern layout to produce pattern groups, and selecting an alternate pattern from the same pattern group to replace a pattern in the pattern group.

In some embodiments, determining the set of candidate fields of view is based on a generation method comprising field of view merging and/or shifting.

In some embodiments, field of view merging and/or shifting comprises combining patterns from different pattern groups into a single candidate field of view.

In some embodiments, field of view merging and/or shifting is based on a proximity of patterns from different pattern groups to each other.

In some embodiments, the prescribed criteria comprises a pattern group diversity metric. In some embodiments, the prescribed criteria comprises a pattern group criticality metric. In some embodiments, the pattern group criticality metric comprises a weight of a pattern group. In some embodiments, the prescribed criteria comprises a subset and/or fields of view quantity metric.

In some embodiments, determining the set of candidate fields of view based on pattern groups of the pattern layout comprises determining the set of candidate fields of view based on an initial list of pattern locations and matching information for the pattern groups.

In some embodiments, the prescribed criteria is set such that patterns included in the one or more subsets of fields of view in combination represent an entirety of the pattern layout or a portion of the pattern layout.

In some embodiments, the prescribed criteria causes inclusion of an optimally diverse group of patterns in a predetermined number of subsets of fields of view.

In some embodiments, the optimally diverse group of patterns comprises a plurality of patterns having geometries that, in combination, represent at least a threshold amount of the pattern layout, given the predetermined number of subsets that form the determined one or more subsets.

In some embodiments, the predetermined number of subsets is set by a user. In some embodiments, the predetermined number of subsets is minimized.

In some embodiments, the method further comprises providing the determined one or more subsets of fields of view as input for model calibration, critical dimension (CD) metrology, and/or defect inspection for a semiconductor lithography process.

In some embodiments, the pattern layout comprises a design layout for a semiconductor wafer.

According to another embodiment, there is provided a non-transitory computer readable medium having instructions thereon, the instructions when executed by a computer causing the computer to perform any of the operations of the method described above.

According to another embodiment, there is provided a system comprising one or more processors configured to perform any of the operations of the method described above.

According to another embodiment, there is provided a non-transitory computer readable medium having instructions thereon, the instructions when executed by a computer causing the computer to perform a method for selecting one or more lists of fields of view of a pattern layout, the method comprising: determining a set of candidate fields of view based on pattern groups of the pattern layout and constraints on characteristics of a given field of view, wherein the characteristics of a given field of view comprise a distance from the given field of view to another field of view and/or a size of the given field of view; and selecting the one or more lists of the fields of view from the set of candidate fields of view according to prescribed criteria for combinations of fields of view included in the one or more lists for scanning electron microscope measurement, wherein selecting the one or more lists comprises: assigning fields of view including specific patterns to respective lists by applying a graph based elimination and graph coloring algorithm, wherein each field of view list corresponds to a color; or assigning fields of view including specific patterns to respective fields of view lists by applying an integer linear programming algorithm and graph coloring algorithm, wherein each field of view corresponds to a color; wherein the prescribed criteria comprises inclusion of an optimally diverse group of patterns in a predetermined number of lists of fields of view.

Other advantages of the embodiments of the present disclosure will become apparent from the following description taken in conjunction with the accompanying drawings, which set forth, by way of illustration and example, certain example embodiments.

### BRIEF DESCRIPTION OF THE DRAWINGS

The accompanying drawings, which are incorporated in and constitute a part of the specification, illustrate one or more embodiments and, together with the description, explain these embodiments. Embodiments will now be described, by way of example only, with reference to the accompanying schematic drawings in which corresponding reference symbols indicate corresponding parts, and in which:

FIG. 1 is a schematic diagram of a lithographic projection apparatus, according to an embodiment.

FIG. 2 depicts a schematic overview of a lithographic cell, according to an embodiment.

FIG. 3 depicts a schematic representation of holistic lithography, representing a cooperation between three technologies to optimize semiconductor manufacturing, according to an embodiment.

FIG. 4 schematically depicts an embodiment of a charged particle (e.g., an electron beam) inspection apparatus, according to an embodiment.

FIG. 5A schematically illustrates an embodiment of a single electron beam inspection apparatus, according to an embodiment.

FIG. 5B schematically illustrates an embodiment of a multi electron beam inspection apparatus, according to an embodiment.

FIG. 6 illustrates a method for selecting one or more subsets (e.g., lists) of fields of view of a pattern layout for scanning electron microscope measurement and/or other inspection, according to an embodiment.

FIG. 7 illustrates how there may be multiple possibilities for lists of fields of view, according to an embodiment.

FIG. 8 provides an alternate illustration of the method shown in FIG. 6, showing various inputs for field of view candidate identification and field of view list selection operations, according to an embodiment.

FIG. 9 illustrates an overview of the field of view candidate identification operation of the method shown in FIG. 6, according to an embodiment.

FIG. 10 illustrates matched instance pattern replacement comprising pattern matching of patterns in a pattern layout to produce pattern groups, and selecting an alternate pattern from the same pattern group to replace a pattern, according to an embodiment.

FIG. 11 illustrates field of view merging and field of view shifting, according to an embodiment.

FIG. 12 illustrates an overview of the field of view list selection operation of the method of FIG. 6, according to an embodiment.

FIG. 13 illustrates assigning fields of view including specific patterns to respective field of view lists by applying a graph based overlapping elimination algorithm comprising a graph coloring algorithm, where each field of view list corresponds to a color, according to an embodiment.

FIG. 14 illustrates assigning fields of view including specific patterns to respective field of view lists by applying an integer linear programming algorithm, according to an embodiment.

FIG. 15 illustrates another non-limiting example of assigning fields of view including specific patterns to respective field of view lists, according to an embodiment.

FIG. 16 is a block diagram of an example computer system, according to an embodiment.

### DETAILED DESCRIPTION

Making extremely small ICs is a complex, time-consuming, and expensive process, often involving hundreds of individual steps. Errors in even one step have the potential to result in defects in the finished IC, thereby rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using optical systems, and/or a scanning electron microscope (SEM), for example.

Several fields of view (FOVs) for an inspection that each include various combinations of patterns from different pattern groups may be used. For example, an initial listing of FOVs that cover certain target pattern groups may be provided for SEM inspection. With the existing manual selection method, for a given pattern list, pattern matching and/or grouping techniques to find replaceable matched instances of pattern groups across a full pattern layout are not considered. This limits the manual selection method's ability to avoid overlap, reduce a required number of FOVs, and/or has other disadvantages. Based on the given pattern list, the existing manual selection method only considers a pattern center for FOV candidate determination, without considering whether pattern merging and/or shifting may be possible to optimize an FOV candidate (e.g., to avoid overlap, reduce a required number of FOVs, etc.). For candidate FOVs generated based on the pattern center, the existing manual selection method discards overlapping FOVs arbitrarily, instead of determining an optimal set of FOVs that cover as wide of a range of pattern geometry as possible in the fewest number of FOVs and/or lists, for example.

The present disclosure provides a mechanism of generating and optimizing FOV lists of a pattern layout selected for metrology, and/or for other purposes. Embodiments of the present disclosure are configured to find matched instances of a pattern through pattern matching or pattern grouping techniques (e.g., to avoid overlap, reduce a required number of FOVs, etc.). Embodiments of the present disclosure can facilitate covering more pattern groups with less FOVs in one or more lists. Embodiments of the present disclosure utilize FOV merging and shifting methods, graph coloring and integer linear programming, and/or other technique to identify FOVs for FOV lists which represent diverse and critical patterns in a pattern layout. With these techniques, users can be provided with a least (and/or otherwise user specified) number of FOVs and/or lists that include diverse and critical patterns for different downstream applications such as model calibration, critical dimension (CD) metrology, hotspot and/or defects detection, etc.

Embodiments of the present disclosure are described in detail with reference to the drawings, which are provided as illustrative examples of the disclosure so as to enable those skilled in the art to practice the disclosure. The figures and examples below are not meant to limit the scope of the present disclosure to a single embodiment, but other embodiments are possible by way of interchange of some or all of the described or illustrated elements. Where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. The present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display (LCD) panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

A (e.g., semiconductor) patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. The design rules may include or specify specific parameters, limits on ranges for parameters, or other information. One or more of the design rule limitations or parameters may be referred to as a “critical dimension” (CD). A critical dimension of a device can be defined as the smallest width of a line or hole or the smallest space between two lines or two holes, or other features. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic semiconductor patterning device that can be used to endow an incoming radiation beam with a patterned cross-section, corresponding to a pattern that is to be created in a target portion of the substrate. Besides the classic mask (transmissive or reflective; binary, phase-shifting, hybrid, etc.), examples of other such patterning devices include a programmable mirror array and a programmable LCD array.

As used herein, the term “patterning process” generally means a process that creates an etched substrate by the application of specified patterns of light as part of a lithography process. However, “patterning process” can also include (e.g., plasma) etching, as many of the features described herein can provide benefits to forming printed patterns using etch (e.g., plasma) processing.

As used herein, the term “pattern” means an idealized pattern that is to be etched on a substrate (e.g., wafer).

As used herein, a “printed pattern” (or a pattern on a substrate) means the physical pattern on a substrate that was etched based on a target pattern. The printed pattern can include, for example, troughs, channels, depressions, edges, or other two and three dimensional features resulting from a lithography process.

As used herein, the term “calibrating” means to modify (e.g., improve or tune) or validate something, such as a model.

A patterning system may be a system comprising any or all of the components described herein, plus other components configured to performing any or all of the operations associated with these components. A patterning system may include a lithographic projection apparatus, a scanner, systems configured to apply or remove resist, etching systems, or other systems, for example.

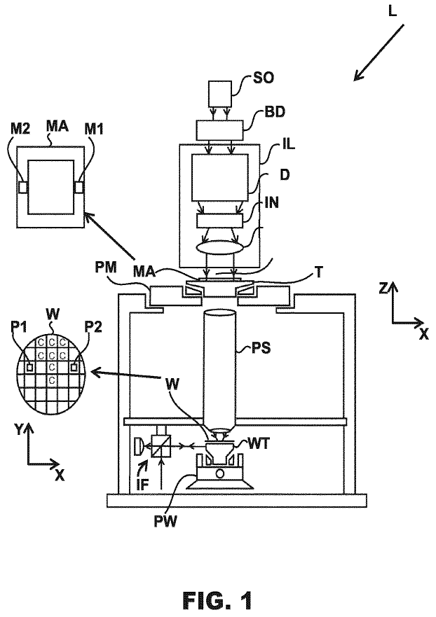

As an introduction, FIG. 1 is a schematic diagram of a lithographic projection apparatus LA, according to an embodiment. LA may be used to produce a patterned substrate (e.g., wafer) as described. The patterned substrate may be inspected/measured by an SEM according to the FOV lists as part of a semiconductor manufacturing process, for example.

Lithographic projection apparatus LA can include an illumination system IL, a first object table T, a second object table WT, and a projection system PS. Illumination system IL, can condition a beam B of radiation. In this example, the illumination system also comprises a radiation source SO. First object table (e.g., a patterning device table) T can be provided with a patterning device holder to hold a patterning device MA (e.g., a reticle), and connected to a first positioner to accurately position the patterning device with respect to item PS. Second object table (e.g., a substrate table) WT can be provided with a substrate holder to hold a substrate W (e.g., a resist-coated silicon wafer), and connected to a second positioner to accurately position the substrate with respect to item PS. Projection system (e.g., which includes a lens) PS (e.g., a refractive, catoptric or catadioptric optical system) can image an irradiated portion of the patterning device MA onto a target portion C (e.g., comprising one or more dies) of the substrate W. Patterning device MA and substrate W may be aligned using patterning device alignment marks M1, M2 and substrate alignment marks P1, P2, for example.

As depicted, the apparatus can be of a transmissive type (i.e., has a transmissive patterning device). However, in general, it may also be of a reflective type, for example (with a reflective patterning device). The apparatus may employ a different kind of patterning device for a classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander, or beam delivery system BD (comprising directing mirrors, the beam expander, etc.). for example. The illuminator IL may comprise adjusting means AD for setting the outer or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus. The radiation beam that it produces may be led into the apparatus (e.g., with the aid of suitable directing mirrors), for example. This latter scenario can be the case when source SO is an excimer laser (e.g., based on KrF, ArF or F2 lasing), for example.

The beam B can subsequently intercept patterning device MA, which is held on a patterning device table T. Having traversed patterning device MA, the beam B can pass through the lens PL, which focuses beam B onto target portion C of substrate W. With the aid of the second positioning means (and interferometric measuring means IF), the substrate table WT can be moved accurately, e.g. to position different target portions C in the path of beam B. Similarly, the first positioning means can be used to accurately position patterning device MA with respect to the path of beam B, e.g., after mechanical retrieval of the patterning device MA from a patterning device library, or during a scan. In general, movement of the tables T, WT can be realized with the aid of a long-stroke module (coarse positioning) and a short-stroke module (fine positioning). However, in the case of a stepper (as opposed to a step-and-scan tool), patterning device table T may be connected to a short stroke actuator, or may be fixed.

The depicted tool can be used in two different modes, step mode and scan mode. In step mode, patterning device table T is kept essentially stationary, and an entire patterning device image is projected in one operation (i.e., a single “flash”) onto a target portion C. Substrate table WT can be shifted in the x or y directions so that a different target portion C can be irradiated by beam B. In scan mode, essentially the same scenario applies, except that a given target portion C is not exposed in a single “flash.” Instead, patterning device table T is movable in a given direction (e.g., the “scan direction”, or the “y” direction) with a speed v, so that projection beam B is caused to scan over a patterning device image. Concurrently, substrate table WT is simultaneously moved in the same or opposite direction at a speed V=Mv, in which M is the magnification of the lens (typically, M=1/4 or 1/5). In this manner, a relatively large target portion C can be exposed, without having to compromise on resolution.

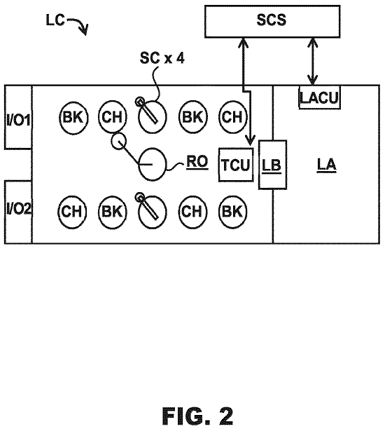

FIG. 2 depicts a schematic overview of a lithographic cell LC. As shown in FIG. 2, a lithographic projection apparatus (shown in FIG. 1 and illustrated as lithographic apparatus LA in FIG. 2) may form part of lithographic cell LC, also sometimes referred to as a lithocell or (litho)cluster, which often also includes apparatus to perform pre- and post-exposure processes on a substrate W. Conventionally, these include spin coaters SC configured to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W (FIG. 1) exposed by the lithographic apparatus LA to be exposed correctly and consistently, it is desirable to inspect substrates to measure properties of patterned structures, such as feature edge placement, overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties using an actual substrate (e.g., a charged particle—SEM—image of a wafer pattern) or an image of an actual substrate, on a latent image (image in a resist layer after the exposure), on a semi-latent image (image in a resist layer after a post-exposure bake step PEB), on a developed resist image (in which the exposed or unexposed parts of the resist have been removed), on an etched image (after a pattern transfer step such as etching), or in other ways.

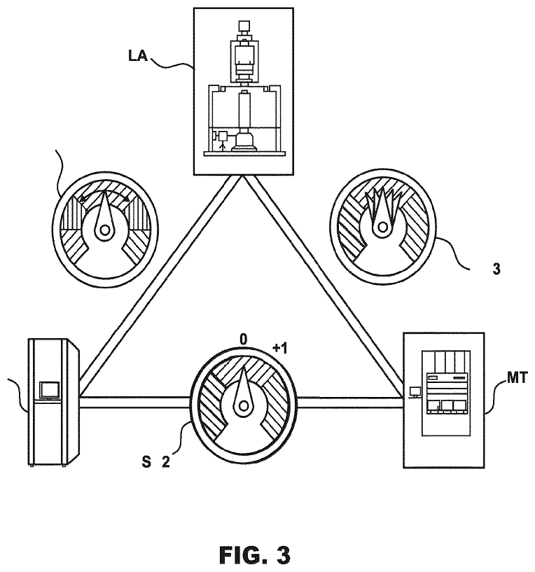

FIG. 3 depicts a schematic representation of holistic lithography, representing a cooperation between three technologies to optimize semiconductor manufacturing. Typically, the patterning process in lithographic apparatus LA is one of the most critical steps in the processing which requires high accuracy of dimensioning and placement of structures on the substrate W (FIG. 1). To ensure this high accuracy, three systems (in this example) may be combined in a so called “holistic” control environment as schematically depicted in FIG. 3. One of these systems is lithographic apparatus LA which is (virtually) connected to a metrology apparatus (e.g., a metrology tool) MT (a second system), and to a computer system CS (a third system). A “holistic” environment may be configured to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CS may use (part of) a design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CS may also be used to detect where within the process window the lithographic apparatus LA is currently operating (e.g. using input from the metrology tool MT) to predict whether defects may be present due to e.g. sub-optimal processing (depicted in FIG. 3 by the arrow pointing “0” in the second scale SC2).

The metrology apparatus (tool) MT may provide input to the computer system CS to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

In lithographic processes, it is desirable to make frequent measurements of the structures created, e.g., for process control and verification. Tools to make such measurements include metrology tool (apparatus) MT. Different types of metrology tools MT for making such measurements are known, including scanning electron microscopes (SEM) or various forms of scatterometer metrology tools MT. In some embodiments, metrology tools MT are or include an SEM.

In some embodiments, metrology tools MT are or include a spectroscopic scatterometer, an ellipsometric scatterometer, or other light based tools. A spectroscopic scatterometer may be configured such that the radiation emitted by a radiation source is directed onto target features of a substrate and the reflected or scattered radiation from the target is directed to a spectrometer detector, which measures a spectrum (i.e. a measurement of intensity as a function of wavelength) of the specular reflected radiation. From this data, the structure or profile of the target giving rise to the detected spectrum may be reconstructed, e.g. by Rigorous Coupled Wave Analysis and non-linear regression or by comparison with a library of simulated spectra. An ellipsometric scatterometer allows for determining parameters of a lithographic process by measuring scattered radiation for each polarization states. Such a metrology tool (MT) emits polarized light (such as linear, circular, or elliptic) by using, for example, appropriate polarization filters in the illumination section of the metrology apparatus. A source suitable for the metrology apparatus may provide polarized radiation as well.

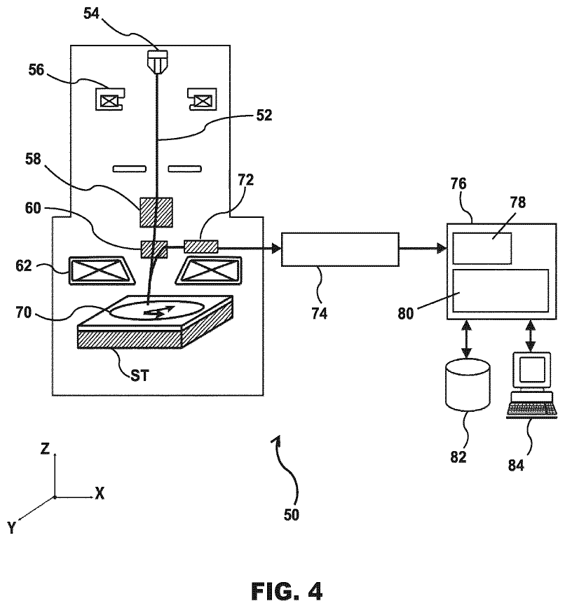

As described above, fabricated devices (e.g., patterned substrates) may be inspected at various points during manufacturing. FIG. 4 schematically depicts a generalized embodiment of an charged particle (electron beam) inspection apparatus (system) 50. In some embodiments, inspection apparatus 50 may be an electron beam or other charged particle inspection apparatus (e.g., the same as or similar to a scanning electron microscope (SEM)) that yields an image of a structure (e.g., some or all the structure of a device, such as an integrated circuit) exposed or transferred on a substrate. A primary electron beam 52 emitted from an electron source 54 is converged by condenser lens 56 and then passes through a beam deflector 58, an E×B deflector 60, and an objective lens 62 to irradiate a substrate 70 on a substrate table ST at a focus.

When the substrate 70 is irradiated with electron beam 52, secondary electrons are generated from the substrate 70. The secondary electrons are deflected by the E×B deflector 60 and detected by a secondary electron detector 72. A two-dimensional electron beam image can be obtained by detecting the electrons generated from the sample in synchronization with, e.g., two dimensional scanning of the electron beam by beam deflector 58 or with repetitive scanning of electron beam 52 by beam deflector 58 in an X or Y direction, together with continuous movement of the substrate 70 by the substrate table ST in the other of the X or Y direction. Thus, in some embodiments, the electron beam inspection apparatus has a field of view for the electron beam defined by the angular range into which the electron beam can be provided by the electron beam inspection apparatus (e.g., the angular range through which the deflector 60 can provide the electron beam 52). Thus, the spatial extent of the field of the view is the spatial extent to which the angular range of the electron beam can impinge on a surface (wherein the surface can be stationary or can move with respect to the field).

As shown in FIG. 4, a signal detected by secondary electron detector 72 may be converted to a digital signal by an analog/digital (A/D) converter 74, and the digital signal may be sent to an image processing system 76. In some embodiments, the image processing system 76 may have memory 78 to store all or part of digital images for processing by a processing unit 80. The processing unit 80 (e.g., specially designed hardware or a combination of hardware and software or a computer readable medium comprising software) is configured to convert or process the digital images into datasets representative of the digital images. In some embodiments, the processing unit 80 is configured or programmed to cause execution of an operation (e.g., FOV list determination and/or optimization processes as) described herein. Further, image processing system 76 may have a storage medium 82 configured to store the digital images and corresponding datasets in a reference database. A display device 84 may be connected with the image processing system 76, so that an operator can conduct necessary operation of the equipment with the help of a graphical user interface.

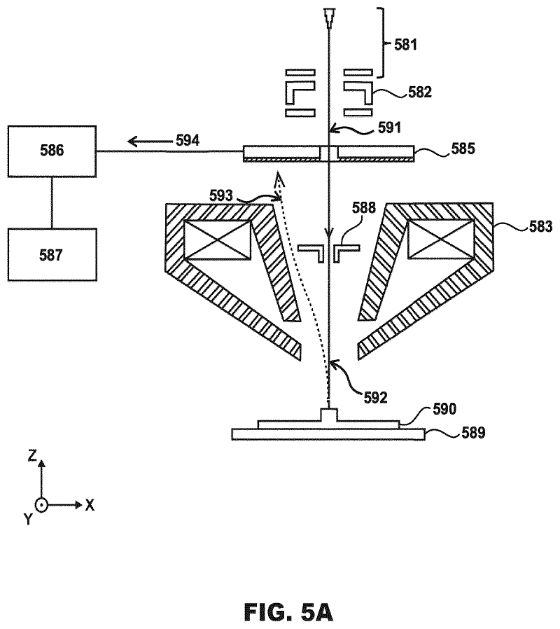

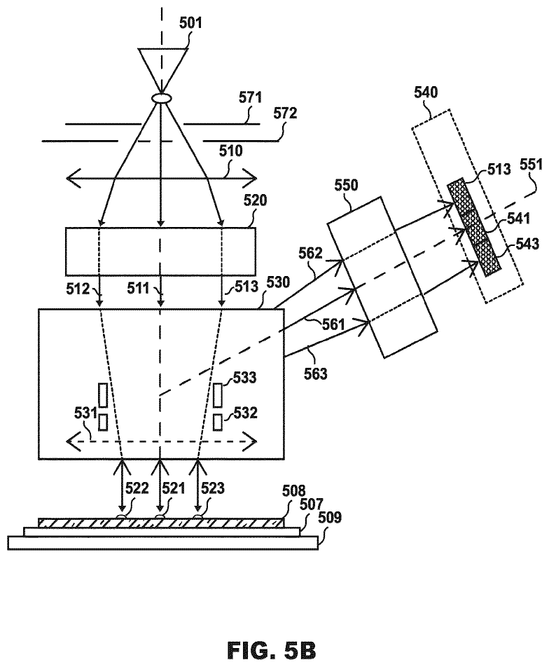

FIG. 5A schematically illustrates an embodiment of a single beam charged particle inspection apparatus (system), such as an SEM. The apparatus is used to inspect a sample 590 (such as a patterned substrate) on a sample stage 589 and comprises a charged particle beam generator 581, a condenser lens module 599, a probe forming objective lens module 583, a charged particle beam deflection module 588, a secondary charged particle detector module 585, an image forming module 586, or other components. The charged particle beam generator 581 generates a primary charged particle beam 591. The condenser lens module 599 condenses the generated primary charged particle beam 591. The probe forming objective lens module 583 focuses the condensed primary charged particle beam into a charged particle beam probe 592. The charged particle beam deflection module 588 scans the formed charged particle beam probe 592 across the surface of an area of interest on the sample 590 secured on the sample stage 589. In some embodiments, the charged particle beam generator 581, the condenser lens module 583, and the probe forming objective lens module 583, or their equivalent designs, alternatives or any combination thereof, together form a charged particle beam probe generator which generates the scanning charged particle beam probe 592.

The secondary charged particle detector module 585 detects secondary charged particles 593 emitted from the sample surface (maybe also along with other reflected or scattered charged particles from the sample surface) upon being bombarded by the charged particle beam probe 592 to generate a secondary charged particle detection signal 594. The image forming module 586 (e.g., a computing device) is coupled with the secondary charged particle detector module 585 to receive the secondary charged particle detection signal 594 from the secondary charged particle detector module 585 and accordingly form at least one scanned image. In some embodiments, the secondary charged particle detector module 585 and image forming module 586, or their equivalent designs, alternatives or any combination thereof, together form an image forming apparatus which forms a scanned image from detected secondary charged particles emitted from sample 590 being bombarded by the charged particle beam probe 592.

In some embodiments, a monitoring module 587 is coupled to the image forming module 586 of the image forming apparatus to monitor, control, etc. the patterning process or derive a parameter for patterning process design, control, monitoring, etc. using the scanned image of the sample 590 received from image forming module 586. In some embodiments, the monitoring module 587 is configured or programmed to cause execution of an operation described herein. In some embodiments, the monitoring module 587 comprises a computing device. In some embodiments, the monitoring module 587 comprises a computer program configured to provide functionality described herein. In some embodiments, a probe spot size of the electron beam in the system of FIG. 5A is significantly larger compared to, e.g., a CD, such that the probe spot is large enough so that the inspection speed can be fast. However, the resolution may be lower because of the large probe spot.

FIG. 5B schematically illustrates an embodiment of a multi-electron beam inspection apparatus (e.g., SEM), according to an embodiment. FIG. 5B is a schematic diagram illustrating an exemplary electron beam tool 504 including a multi-beam inspection tool. It will be understood that the multi-beam electron beam tool is intended to be illustrative only and not to be limiting. The present disclosure can also work with a single charged-particle beam imaging system (e.g., as described above). As shown in FIG. 5B, electron beam tool 504 comprises an electron source 501 configured to generate a primary electron beam, a Coulomb aperture plate (or “gun aperture plate”) 571 configured to reduce Coulomb effect, a condenser lens 510 configured to focus primary electron beam, a source conversion unit 520 configured to form primary beamlets (e.g., primary beamlets 511, 512, and 513), a primary projection system 530, a motorized stage, and a sample holder 507 supported by the motorized stage to hold a wafer 508 to be inspected. Electron beam tool 504 may further comprise a secondary projection system 550 and an electron detection device 540. Primary projection system 530 may comprise an objective lens 531. Electron detection device 540 may comprise a plurality of detection elements 541, 542, and 543. A beam separator 533 and a deflection scanning unit 532 may be positioned inside primary projection system 530.

Electron source 501, Coulomb aperture plate 571, condenser lens 510, source conversion unit 520, beam separator 533, deflection scanning unit 532, and primary projection system 530 may be aligned with a primary optical axis of tool 504. Secondary projection system 550 and electron detection device 540 may be aligned with a secondary optical axis 551 of tool 504.

Controller 509 may be connected to various components, such as source conversion unit 520, electron detection device 540, primary projection system 530, or a motorized stage. In some embodiments, as explained in further details below, controller 509 may perform various image and signal processing functions. Controller 509 may also generate various control signals to control operations of one or more components of the charged particle beam inspection system.

Deflection scanning unit 532, in operation, is configured to deflect primary beamlets 511, 512, and 513 to scan probe spots 521, 522, and 523 across individual scanning areas in a section of the surface of wafer 508. In response to incidence of primary beamlets 511, 512, and 513 or probe spots 521, 522, and 523 on wafer 508, electrons emerge from wafer 508 and generate three secondary electron beams 561, 562, and 563. Each of secondary electron beams 561, 562, and 563 typically comprise secondary electrons (having electron energy≤50 eV) and backscattered electrons (having electron energy between 50 eV and the landing energy of primary beamlets 511, 512, and 513). Beam separator 533 is configured to deflect secondary electron beams 561, 562, and 563 towards secondary projection system 550. Secondary projection system 550 subsequently focuses secondary electron beams 561, 562, and 563 onto detection elements 541, 542, and 543 of electron detection device 540. Detection elements 541, 542, and 543 are arranged to detect corresponding secondary electron beams 561, 562, and 563 and generate corresponding signals which are sent to controller 509 or a signal processing system (not shown), e.g., to construct images of the corresponding scanned areas of wafer 508.

In some embodiments, detection elements 541, 542, and 543 detect corresponding secondary electron beams 561, 562, and 563, respectively, and generate corresponding intensity signal outputs (not shown) to an image processing system (e.g., controller 509). In some embodiments, each detection elements 541, 542, and 543 may comprise one or more pixels. The intensity signal output of a detection element may be a sum of signals generated by all the pixels within the detection element.

In some embodiments, controller 509 may comprise an image processing system that includes an image acquirer (not shown) and a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detection device 540 of tool 504 through a medium such as an electrical conductor, optical fiber cable, portable storage media, IR, Bluetooth, internet, wireless network, wireless radio, among others, or a combination thereof. In some embodiments, the image acquirer may receive a signal from electron detection device 540 and may construct an image. The image acquirer may thus acquire images of wafer 508. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, the image acquirer may acquire one or more images of a sample based on one or more imaging signals received from electron detection device 540. An imaging signal may correspond to a scanning operation for conducting charged particle imaging. An acquired image may be a single image comprising a plurality of imaging areas or may involve multiple images. The single image may be stored in the storage. The single image may be an original image that may be divided into a plurality of regions. Each of the regions may comprise one imaging area containing a feature of wafer 508. The acquired images may comprise multiple images of a single imaging area (e.g., an FOV) of wafer 508 sampled multiple times over a time sequence or may comprise multiple images of different imaging areas of wafer 508. The multiple images may be stored in the storage. In some embodiments, controller 509 may be configured to perform image processing steps with the multiple images of the same location of wafer 508.

In some embodiments, controller 509 may include measurement circuitries (e.g., analog-to-digital converters) to obtain a distribution of the detected secondary electrons. The electron distribution data collected during a detection time window, in combination with corresponding scan path data of each of primary beamlets 511, 512, and 513 incident on the wafer surface, can be used to reconstruct images of the wafer structures under inspection. The reconstructed images can be used to reveal various features of the internal or external structures of wafer 508, and thereby can be used to reveal any defects that may exist in the wafer.

In some embodiments, controller 509 may control the motorized stage to move wafer 508 during inspection of wafer 508. In some embodiments, controller 509 may enable the motorized stage to move wafer 508 in a direction continuously at a constant speed. In other embodiments, controller 509 may enable the motorized stage to change the speed of the movement of wafer 508 over time depending on the steps of scanning process.

Although electron beam tool 504 as shown in FIG. 5B uses three primary electron beams, it is appreciated that electron beam tool 504 may use a single charged-particle beam imaging system (“single-beam system”), or a multiple charged-particle beam imaging system (“multi-beam system”) with two or more number of primary electron beams. The present disclosure does not limit the number of primary electron beams used in electron beam tool 504.

As described above, it may be desirable to use one or more tools to produce results that, for example, can be used to design, control, monitor, etc., a patterning process. One or more tools used in computationally controlling, designing, etc. one or more aspects of the patterning process, such as the pattern design for a patterning device (including, for example, adding sub-resolution assist features or optical proximity corrections), the illumination for the patterning device, etc., may be provided. Accordingly, in a system for computationally controlling, designing, etc. a manufacturing process involving patterning, the manufacturing system components or processes can be described by various functional modules or models. In some embodiments, one or more electronic (e.g., mathematical, parameterized, etc.) models may be provided that describe one or more steps or apparatuses of the patterning process. In some embodiments, a simulation of the patterning process can be performed using one or more electronic models to simulate how the patterning process forms a patterned substrate using a design pattern provided by a patterning device.

Images, from, e.g., the system of FIG. 4, FIG. 5A, and/or FIG. 5B, may be processed to extract dimensions, shapes, contours, or other information that describe the edges of objects, representing semiconductor device structures, in the image. The shapes, contours, or other information may be quantified via metrics, such as edge placement error (EPE), CD, etc. at user-defined cut-lines or in other locations. These shapes, contours, or other information may be used to optimize a patterning process, for example. Information from the images may be used for model calibration, defect inspection, and/or for other purposes.

It should be understood that the method of the present disclosure, while sometimes described in reference to an SEM, can be applied to or on any suitable metrology tool where determining optimal FOVs is advantageous, such as an SEM, an X-ray diffractometer, an ultrasound, an optical imaging device, etc. Additionally, the operations described herein can be applied in multiple metrology apparatuses, steps, or determinations.

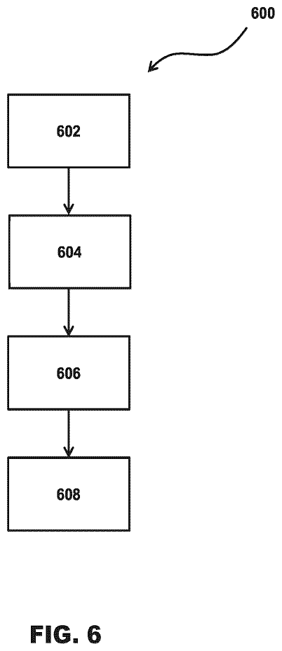

FIG. 6 illustrates an exemplary method 600 for selecting one or more subsets of FOVs of a pattern layout for SEM measurement and/or other metrology according to an embodiment of the present disclosure. A FOV of a pattern layout is an area of the pattern layout that can be imaged at the same time (e.g. in one image) by the sensor(s) of the SEM (or other metrology tool). A FOV is what is “visible” to the sensor(s) of the SEM with the sensor(s) at a particular position and orientation in space relative to the pattern layout (e.g., as patterned onto a patterned substrate). A FOV often has a substantially rectangular shape, with a length and width, but may also have other shapes (e.g., circular, oval, square, etc.). For example, an FOV typically has a square shape with a certain side length, or a rectangular shape with a certain length and a width. Subsets may be lists, groups, and/or other aggregations. The pattern layout may comprise a design layout for a semiconductor wafer, for example. Method 600 comprises grouping patterns of a pattern layout into pattern groups (operation 602), determining a set of candidate FOVs (operation 604), selecting the one or more subsets (e.g., lists) of the FOVs from the set of candidate FOVs according to prescribed criteria (operation 606), and providing the determined one or more subsets of FOVs as input for model calibration, critical dimension (CD) metrology, defect inspection and/or other input for a semiconductor lithography process (operation 608).

In some embodiments, a non-transitory computer readable medium stores instructions which, when executed by a computer, cause the computer to execute one or more of operations 602-608, or other operations. The operations of method 600 are intended to be illustrative. In some embodiments, method 600 may be accomplished with one or more additional operations not described, or without one or more of the operations discussed. For example, in some embodiments, operations 602 and/or 608 may be eliminated from method 600. Additionally, the order in which the operations of method 600 are illustrated in FIG. 6 and described herein is not intended to be limiting.

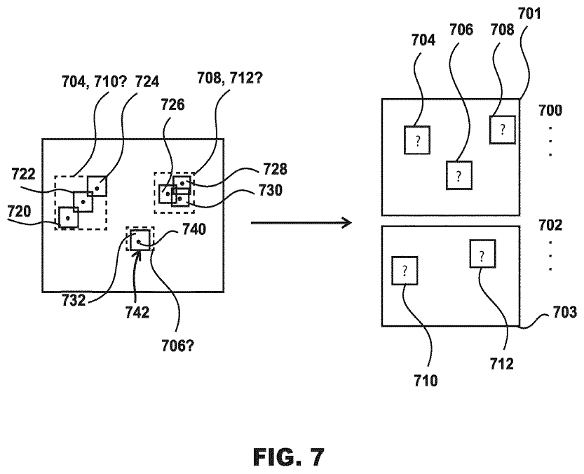

FIG. 7 illustrates multiple possibilities for subsets (e.g., lists) 700, 702 of FOVs 704-712 (e.g., as indicated by the question marks). In this example, lists 700 and 702 comprise collections 701, 703 of FOVs determined based on different pattern groups 720-732 (with a pattern center 740 and pattern FOV 742 indicated for each pattern group 720-732). Each FOV 704-712 may include patterns from one or more pattern groups 720-732 so that the FOVs 704-712 included in lists 700 and 702 in combination cover pattern groups 720-732. The pattern groups may be covered with a certain amount of pattern diversity, considering relative pattern group importance, any maximum, minimum, prescribed, threshold, reduced number, increased number, allowable, etc., list and/or FOV count, and/or other factors. Pattern groups 720-732 that can be included in a given FOV 704-712 may be limited by FOV size, a (minimum, maximum, prescribed threshold, allowable, etc.) distance between FOVs, the (minimum, maximum, prescribed threshold, allowable, etc.) allowable list and/or FOV count, overlap between pattern FOVs 742, and/or other factors. Method 600 (FIG. 6) is configured to determine a least (and/or otherwise user specified) number lists 700, 702 and/or FOVs 704-712 that include the most diverse and critical patterns for different downstream applications such as model calibration, critical dimension (CD) metrology, hotspot and/or defects detection, etc.

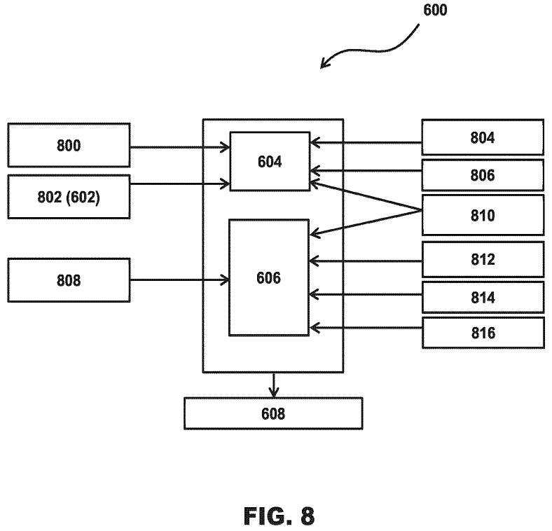

FIG. 8 provides an alternate illustration of method 600, showing various example inputs 800-816 for operations 604 (FOV candidate identification) and 606 (FOV subset (e.g., FOV list) selection). As shown in FIG. 8, example inputs for FOV candidate identification (operation 604) may include the pattern groups (e.g., determined at operation 602 shown in FIG. 6 and discussed below), an initial list of pattern locations 800, an FOV size 804, a candidate generation method 806, and a minimum allowable distance between FOVs 810. Example inputs for FOV list selection (operation 606) may include minimum allowable distance between FOVs 810, pattern group criticality (e.g., weight) information 808, a weight order 812, a (minimum, maximum, prescribed threshold, allowable, etc.) FOV list count 814, and an FOV optimization method 816, for example. Each of these inputs, in relation to operations 604 and/or 606, is further described below. Method 600 is configured to determine a (minimum, maximum, prescribed threshold, allowable, etc., and/or otherwise user specified) number lists and/or FOVs that include diverse and critical patterns and provide (operation 608) them for SEM inspection and/or metrology. SEM results may be provided for different downstream applications such as model calibration, critical dimension (CD) metrology, hotspot and/or defects detection, etc., again as further discussed below.

Returning to FIG. 6, at operation 602, patterns of a pattern layout are grouped into groups. The grouping comprises pattern matching to produce the pattern groups. For example, a representation of a pattern layout may be received. The representation may be received electronically from one or more other portions of the present system (e.g., from a different processor, or from a different portion of a single processor), from a remote computing system not associated with a present system, and/or from other sources. The representation may be received wirelessly and/or via wires, via a portable storage medium, and/or from other sources. The representation may be uploaded and/or downloaded from another source, such as cloud storage for example, and/or received in other ways.

The representation of the pattern layout may be and/or include all or substantially all of the patterns of a pattern layout. The representation may comprise a simulation, an image, an electronic file, a target polygon design, and/or other representations. The representation may include information describing patterns of the pattern layout themselves and/or information related to the patterns. The patterns may include the geometrical shapes of contours in the pattern layout and/or information related to the geometrical shapes. Using a semiconductor chip as an example, a representation of a pattern layout may include all (or substantially all) of the patterns that make up a chip design (e.g., including pattern layout structures configured to facilitate inspections and/or other operations). This may include channels, protrusions, vias, gratings, etc., as shown in a simulation, an image, a .GDS file, etc.

Grouping the patterns of the pattern layout into groups may be based on relative similarity of between patterns, and/or information associated with the patterns. For example, the grouping may be based on pattern polygons obtained directly from a layout design. In some embodiments, the pattern grouping may be based on pattern images or contours of the pattern layout, where the images or contours can be obtained from any suitable inspection or metrology system, or simulation. For example, the grouping may be based on aerial images, optical images, mask images, resist images, etch images, wafer image of the patterns as measured or simulated.

The patterns in a pattern layout may include two and/or three dimensional geometrical shapes, for example. The received representation includes data that describes the characteristics of the shapes (e.g., such as X-Y dimensional data points, a mathematical equation that describes the geometrical shape, etc.), processing parameters associated with the shapes, and/or other data. In some embodiments, the representation of the pattern layout may comprise inspection results from an after development inspection (ADI) for the pattern layout (e.g., from a previously inspected wafer), a model of the pattern in the pattern layout, and/or other information. The inspection results from the after development inspection for the pattern layout may be obtained from an SEM, an optical metrology tool, and/or other sources. In some embodiments, the patterns may be obtained from aerial images, mask images, etch images, or etc., that result from a resist model, an optical model, an etch model, an etch bias model and/or other modelling sources. In some embodiments, the representation of the pattern layout comprises a .GDS file, a .GDSII file, a .OASIS file, and/or an electronic file having other file formats, and/or another electronic representation of the pattern layout.

Pattern grouping may be based on this information, for example. Individual patterns (which may include identical and/or similar patterns as described above) may have repeating instances across a full pattern layout. Individual patterns may be identified, with repeating (identical or nearly identical, e.g., similar or like) patterns grouped together. The grouping may be performed, for example, by exact and/or fuzzy matching algorithms, clustering, machine learning, or any other grouping method or process that is known in the art. Repeating patterns may be grouped across the full pattern layout.

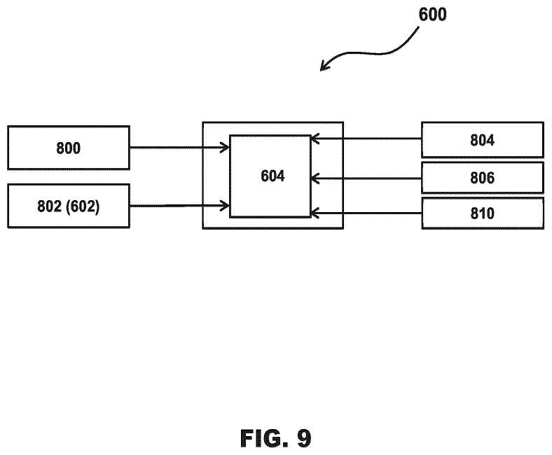

At operation 604, a set of candidate FOVs are determined. As described above, an FOV includes a portion of the pattern layout. The candidate FOVs may be determined based on constraints on characteristics of a given field of view, the pattern groups of the pattern layout, a generation method, and/or other information. FIG. 9 illustrates an overview of operation 604 of method 600. As shown in FIG. 9, example inputs for FOV candidate identification (operation 604) may include the pattern groups (e.g., determined at operation 602 shown in FIG. 6 and discussed above), a list of pattern locations 800, an FOV size 804 (e.g., a constraint on a characteristic of an FOV), a candidate generation method 806, and a minimum allowable distance between FOVs 810 (e.g., another constraint on a characteristic of an FOV).

The characteristics of a given FOV may comprise a distance from the given FOV to another FOV, a size of the given FOV, and/or other characteristics. Constraints on these characteristics may include, for example, a minimum threshold distance between FOVs, a (minimum, maximum, prescribed threshold, allowable, etc.) size of an FOV, an actual size of the FOV for a given SEM, and/or other constraints. The distance from a given FOV to another FOV may be a distance across a pattern layout between the closest (e.g., rectangular) edges of the two FOVs. The distance from a given FOV to another FOV may be a distance in an “x” direction across a pattern layout, a “y” direction, and/or a combination thereof. The distance between FOVs may be large enough to prevent charging of imaged structures by an SEM, provide clear and separate images of pattern structures in each FOV, and/or may be configured in other ways. In some embodiments, the distance from a given FOV to another FOV is at least about 1-4 μm, depending on the inspection tool.

The size of an FOV may comprise the area imaged in the FOV, and/or the extent of an area of the pattern layout that fits within an FOV. Depending on the shape of the FOV, an FOV may have a length, width, diameter, radii, and/or other dimensions that describe the size of the FOV. Typically the size of an FOV is SEM (or other metrology tool) dependent. In some embodiments, the size of a FOV is about 1-12 square μm, depending on the inspection tool.

In some embodiments, determining the set of candidate FOVs is based on the pattern groups in a pattern layout, a candidate FOV generation method, and/or other factors. For example, in some embodiments, determining the set of candidate FOVs based on pattern groups of the pattern layout and/or based on a candidate FOV generation method comprises determining the set of candidate FOVs based on an initial list of pattern locations and matching information for the pattern groups. This may be a seed pattern list is a list comprising a baseline or initial listing of FOVs that cover certain target pattern groups of interest provided for SEM inspection. Determining the set of candidate FOVs based on a list of pattern locations and matching information for the pattern groups may comprise matched instance pattern replacement for the set of candidate FOVs, for example. The matched instance pattern replacement comprises pattern matching of patterns in the pattern layout to produce pattern groups (e.g., operation 602), and selecting an alternate pattern from the same pattern group to replace a pattern in the pattern group.

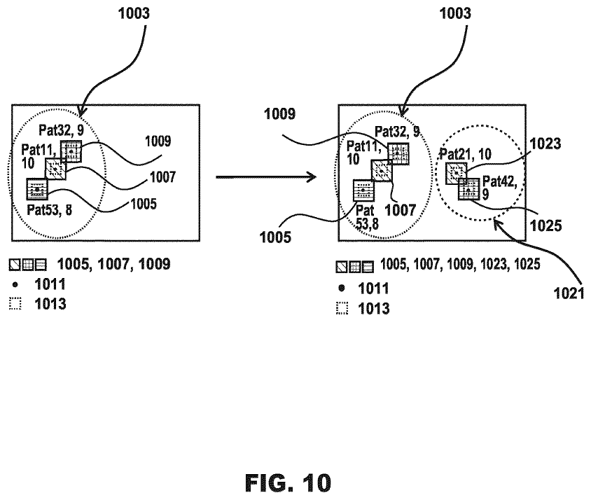

For example, FIG. 10 illustrates matched instance initial (e.g., “seed”) pattern replacement comprising pattern matching of patterns in the pattern layout to produce pattern groups (e.g., operation 602), and selecting an alternate pattern in a different location from the same pattern group to replace a pattern. FIG. 10 illustrates initial 1003 FOV candidates 1005, 1007, 1009, determined based on initial (seed) patterns (for example). FOV candidates 1005, 1007, and 1009 include a pattern 53 of a pattern group 8 (in this example), a pattern 32 of a pattern group 9, and a pattern 11 of a pattern group 10. (FIG. 10 also shows a pattern center 1011 and a pattern FOV 1013 for each pattern.) However, initial 1003 FOV candidate 1005 overlaps with FOV candidate 1007, and FOV candidate 1007 overlaps with FOV candidate 1009. Because of this overlap, FOV candidates 1023, 1025 from matching pattern instances are identified 1021. FOV candidates 1023 and 1025 include a different pattern 21 from pattern group 10 (in this example), and a different pattern 42 from pattern group 9. These matched instances of the patterns can be used to select an alternate pattern in a different location from the same pattern group to replace a pattern in the pattern group for one or more FOV lists. In this example, candidate FOVs after matched instance seed pattern replacement may include FOVs 1005 and 1009, and FOV 1023, which is spaced apart from, and does not overlap FOV 1005 or 1009.

In some embodiments, the candidate FOV generation method comprises FOV merging and/or shifting. FOV merging and/or shifting comprises combining patterns from different pattern groups into a single candidate field of view. FOV merging and/or shifting is based on a proximity of patterns from different pattern groups to each other and/or other information.

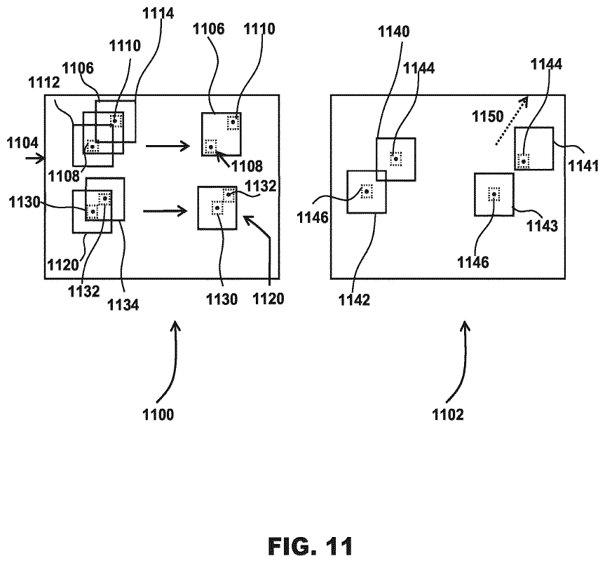

For example, FIG. 11 illustrates FOV merging 1100 and FOV shifting 1102. In some embodiments, FOV merging may include determining 1104 an FOV 1106 candidate that encompasses different patterns of interest 1108, 1110 that were each included in two different initial possible FOVs 1112, 1114. FOV 1106 does not overlap with any other FOVs (e.g., unlike FOV 1112 and 1114 which overlap with each other.) In some embodiments, FOV merging may include selecting an initial possible FOV 1120 that encompasses different patterns of interest 1130, 1132, even if one of the patterns of interest (e.g., 1132) was originally included in a different initial possible FOV 1134. FOV shifting 1102 comprises shifting 1150 the position of one or more initial possible FOVs 1140, 1142 to determine candidate FOVs 1141, 1143, even if a pattern 1144 is no longer centered in an FOV, so that the initial possible FOVs 1140 and 1142 no longer overlap, and both can be candidate FOVs, each including different patterns 1144 and 1146.

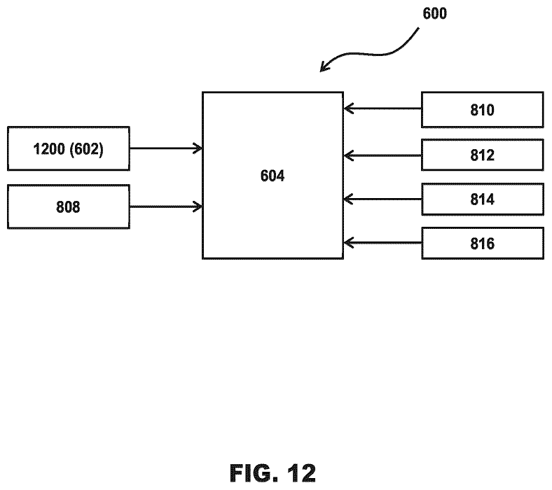

Returning to FIG. 6, at operation 606, one or more subsets of the FOVs from the set of candidate FOVs are selected according to prescribed criteria. A subset may be a list, a group, and/or other aggregations, for example. In some embodiments, each of the one or more subsets corresponds to an FOV list. A subset of FOVs comprises a list of FOVs selected from the set of candidate FOVs. FIG. 12 illustrates an overview of operation 606 of method 600. As shown in FIG. 12, example inputs for FOV subset (e.g., list) selection (operation 606) may include the candidate FOVs (e.g., determined at operation 604 shown in FIG. 6 and discussed above), minimum allowable distance between FOVs 810, pattern group criticality (e.g., weight) information 808, a weight order 812, a (minimum, maximum, prescribed threshold, allowable, etc.) FOV list count 814, and an FOV optimization method 816.

The prescribed criteria is for combinations of FOVs included in the one or more subsets for scanning electron microscope (SEM) measurement and/or other metrology. The selected one or more subsets (e.g., lists) each comprises a number of FOVs that individually (e.g., within a list) and/or collectively (e.g., across a set of lists) meet the prescribed criteria. In some embodiments, the prescribed criteria is set such that patterns included in the one or more subsets of FOVs, in combination, represent an entirety of the pattern layout or a portion of the pattern layout. In some embodiments, the prescribed criteria causes inclusion of an optimally diverse group of patterns in a predetermined number of subsets (lists) of FOVs. The optimally diverse group of patterns comprises a plurality of patterns having geometries that, in combination, represent at least a threshold amount of the pattern layout, given the predetermined number of subsets of FOVs that form the determined one or more subsets. The predetermined number of subsets may be set by a user, determined automatically, and/or determined in other ways. In some embodiments, the predetermined number of subsets is minimized.

For example, in some embodiments, the selected one or more subsets (lists) of FOVs contain an optimally diverse set of pattern groups, in less than a prescribed limit number of subsets. The optimally diverse set of pattern groups comprises a plurality of pattern groups having geometries that, in combination, represent as much of the pattern layout as possible, given the predetermined number of subsets (lists) of FOVs that form the one or more selected subsets. Phrased another way, the selected one or more subsets (lists) may have FOVs that include as many geometrically unique patterns of the pattern layout as possible in a (minimum, maximum, prescribed threshold, allowable, etc.) allowable number of subsets (lists).

In some embodiments, the prescribed criteria comprises a pattern group diversity metric, a pattern group criticality metric, a subset (e.g., list) and/or FOV quantity metric, and/or other metrics. In some embodiments, the diversity metric may specify a pattern group count (e.g., the higher the pattern group count the higher the diversity), an amount and/or percentage of a pattern layout that is to be represented in the lists of FOVs, a range of patterns and/or pattern groups that should be included in the lists of FOVs, and/or other diversity metrics. In some embodiments, the criticality metric comprises a priority of a pattern group, a weight of a pattern group, a score associated with a pattern group, a weight order and/or order of importance of pattern groups, and/or other metrics. In some embodiments, a criticality metric can be any attribute used to define a pattern or pattern group priority (e.g., minimum CD, pattern density, etc.). In some embodiments, the subset and/or FOV quantity metric comprises a threshold number of lists and/or FOVs. In some embodiments, the prescribed criteria comprises inclusion of a maximum threshold number of lists and/or FOVs. The threshold number is configured to ensure that, in combination with other criteria, the FOVs included in the selected subset(s) (list(s)) provide adequate pattern overage, for example representing an entirety (or almost an entirety) of the pattern layout, for example.

A pattern group diversity metric, a pattern group criticality metric, a list and/or FOV quantity metric, and/or other criteria may be set by a user (e.g., via a user interface as described below); set automatically based on the patterns in the pattern layout and/or the pattern groups, the number of candidate FOVs of the pattern layout, and/or other information; and/or set in other ways. For example, user determined criteria may be configured such that the one or more subsets (lists) may be configured to include a (minimum, maximum, prescribed threshold, allowable, etc.) representative number of each geometrically unique pattern in the minimum (or fewest possible) number of FOVs.

According to embodiments of the present disclosure, FOV generation or optimization can include selecting the one or more subsets (e.g., lists of FOVs) comprises assigning FOVs including specific patterns to respective FOV lists by applying a graph based overlapping elimination algorithm. The graph based overlapping elimination algorithm comprises a graph coloring algorithm, where each FOV list corresponds to a color. The prescribed criteria is configured such that the graph based elimination and/or graph coloring algorithm outputs an optimally diverse group of patterns in a predetermined number of lists of FOVs.

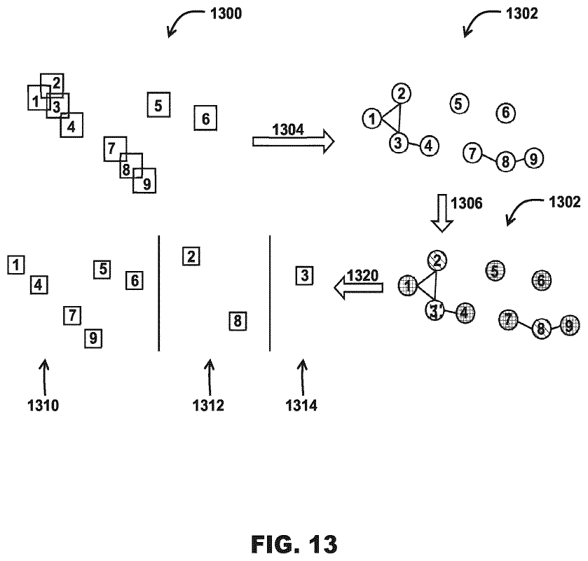

For example, FIG. 13 illustrates assigning FOVs including specific patterns to respective FOV lists by applying a graph based overlapping elimination algorithm comprising a graph coloring algorithm according to an embodiment of the present disclosure, where each FOV list corresponds to a respective color. FIG. 13 illustrates several possible FOV candidates 1300 (labeled 1-9). An intersection graph 1302 is constructed 1304 and colored 1306 (e.g., shaded in this example). Overlapping FOVs are associated. For example, intersection graph 1302 illustrates any overlapping FOVs (e.g., 1-4 and 7-9) as linked circles. Based on the overlapping related association (e.g., as illustrated by links) the patterns are assigned to different colors such that overlapping patterns do not belong to the same color or FOV list. The colors in the colored 1306 intersection graph 1302 illustrate the linked FOVs that may possibly be included in a single FOV list (e.g., because those specific FOVs do not overlap with each other). A corresponding FOV list 1310, 1312, and 1314 is output 1320 for each color.

According to other embodiments of the present disclosure, FOV generation or optimization can include selecting the one or more subsets comprises assigning FOVs including specific patterns to respective FOV lists by applying an integer linear programming algorithm. In some embodiments, selecting the one or more subsets comprises assigning FOVs including specific patterns to respective FOV lists by applying the integer linear programming algorithm. The prescribed criteria is configured such that the integer linear programming and/or graph coloring algorithm outputs an optimally diverse group of patterns in a predetermined number of lists of FOVs. The integer linear programming may enforce user defined constraints such that, for example, critical patterns and/or pattern groups are selected based on group weight, the total list count is less than a prescribed limit, pattern coverage is maximized with a minimum FOV count, etc.

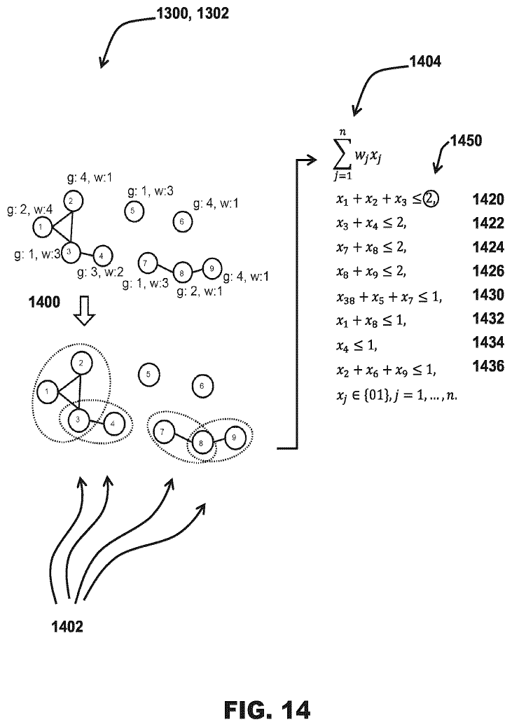

For example, FIG. 14 illustrates assigning FOVs including specific patterns to respective FOV lists by applying an integer linear programming algorithm, according to an embodiment of the present disclosure. Some or all of the variables in the integer linear programming algorithm are integers. In some embodiments, the integer linear programming algorithm and associated constraints (described below) are linear. The integer linear programming enforces defined constraints such that, for example, critical patterns and/or pattern groups are selected based on group weight, the total list count is less than a prescribed limit, and pattern coverage is maximized with a minimum FOV count.

FIG. 14 again illustrates FOV candidates 1300 (labeled 1-9) in an intersection graph 1302, in which ‘g’ and ‘w’ stand for a candidate's group ID and weight, respectively. Intersection graph 1302 illustrates any overlapping FOVs (e.g., 1-4 and 7-9) as linked circles. FIG. 14 illustrates a group identification and a group weight for each circle in intersection graph 1302. FIG. 14 illustrates finding 1400 all maximal cliques 1402, and maximizing Equation 1404 subject to various clique constraints 1420-1426 (in this example) and/or group constraints 1420-1436 (in this example). A clique 1402 of graph 1302 is a complete subgraph of graph 1302. That is, it is a subgraph of 1302 in which each pair of vertices is connected by an edge. In Equation 1404, n is the number of patterns (i.e., n=9 in this example), wⱼ is the weight (w) of a given pattern (j), and xⱼ is a Boolean variable indicating whether the FOV corresponding to pattern (j) is selected or not (1: selected, 0: not selected). In clique constraints 1420-1426, each constraint represents a clique, and a maximum FOV list count 1450 is defined at the end of each constraint, meaning that for each clique, the number of FOVs being selected must not exceed the maximum FOV list count, since all the FOVs within a clique are mutually overlapping. In group constraints 1430-1436, each constraint represents a pattern group, meaning that for each group, the number of FOVs being selected is at most one (for FOV count minimization).

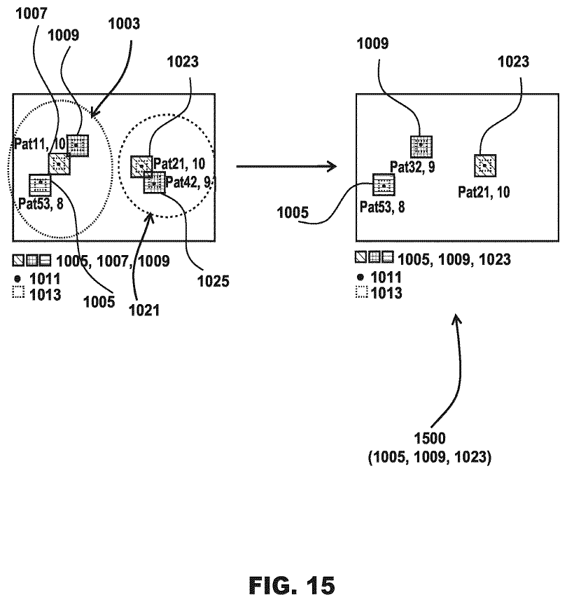

FIG. 15 illustrates another non-limiting example of assigning FOVs including specific patterns to respective FOV lists (e.g., operation 606 in FIG. 6). Like FIG. 10, FIG. 15 illustrates matched instance pattern replacement comprising pattern matching of patterns in the pattern layout to produce pattern groups (e.g., operation 602), and selecting an alternate pattern from the same pattern group to replace an initial (or “seed”) pattern. FIG. 15 illustrates initial 1003 FOV candidates 1005, 1007, 1009, determined based on initial patterns. FOV candidates 1005, 1007, and 1009 include a pattern 53 of a pattern group 8 (in this example), a pattern 32 of a pattern group 9, and a pattern 11 of a pattern group 10. (FIG. 15 also shows a pattern center 1011 and a pattern FOV 1013 for each pattern.) However, initial 1003 FOV candidate 1005 overlaps with FOV candidate 1007, and FOV candidate 1007 overlaps with FOV candidate 1009. Because of this overlap, FOV candidates 1023, 1025 from matching pattern instances are identified 1021. FOV candidates 1023 and 1025 include a different pattern 21 from pattern group 10 (in this example), and a different pattern 42 from pattern group 9. These matched instances of the patterns can be used to select an alternate pattern from the same pattern group to replace a pattern in the pattern group for an FOV list 1500. In this example, FOVs in a list after matched instance pattern replacement include FOVs 1005 and 1009, and FOV 1023, which is spaced apart from, and does not overlap FOV 1005 or 1009.

Returning to FIG. 6, at operation 608, the determined one or more subsets of FOVs are provided for SEM inspection and/or metrology. SEM results may be provided for various downstream processes. For example, a patterned substrate may be inspected with an SEM according to the FOV lists. The patterned substrate may be inspected to determine one or more dimensions of the patterned substrate, detect defects, or determine other information. The one or more determined dimensions may comprise a critical dimension (CD), critical dimension uniformity (CDU), edge placement error (EPE), local placement error (LPE), local critical dimension uniformity (LCDU), line edge roughness (LER), and line width roughness (LWR), or other dimensions. Defects may include pattern shifts, stochastic defects, and/or other defects. The SEM system is configured to generate images that correspond to listed FOVs and include information describing the geometrical shapes of contours in a pattern, or information related to the geometrical shapes. The geometrical shapes of the contours in the pattern may be two dimensional geometrical shapes, for example. The images include data that describes the characteristics of the contours (e.g., such as X-Y dimensional data points, a mathematical equation that describes a geometrical shape, etc.), processing parameters associated with the contour, or other data. The images may further include 3D information, such as information about features that are buried in one or more sub-layers, data from prior inspections of prior layers, information selected and input by a user operating inspection system that generates the inspection images, or other information.

In some embodiments, the data associated with the SEM inspection according to the FOV lists can be used as calibration data for a physical, semi-physical or empirical model, or used as training data for training a machine learning model. In some embodiments, the data associated with the SEM inspection according to the FOV lists may be provided as input to a trained machine learning model for the purpose of generating a prediction (output) from the model (e.g., a prediction about a semiconductor manufacturing process). Providing may include electronically sending, uploading, and/or otherwise inputting information to a machine learning simulation model. In some embodiments, the simulation model may be integrally programmed with the instructions that cause others of operations 602-608 (e.g., such that no “providing” is required, and instead data simply flows directly to a simulation model).

For example, data may be provided to one or more machine learning simulation models. A simulation model may be configured to predict an impact one or more geometrically unique features may have on the patterning process (e.g., as described above). For example, a machine learning model may be associated with optical proximity correction (OPC), hotspot or defect prediction, and/or source mask optimization (SMO) for a semiconductor lithography process, and/or other operations. Selecting optimal subset(s) (list(s)) of FOVs for training can save runtime during model training and/or execution operations, and/or have other advantages.

Adjustments to a semiconductor manufacturing process may be made based on the SEM inspection, model outputs, and/or other information. Adjustments may including changing one or more semiconductor manufacturing process parameters, for example. Adjustments may include pattern parameter changes (e.g., sizes, locations, and/or other design variables), and/or any adjustable parameter such as an adjustable parameter of the etching system, the source, the patterning device, the projection optics, dose, focus, etc. Parameters may be automatically or otherwise electronically adjusted by a processor (e.g., a computer controller), modulated manually by a user, or adjusted in other ways. In some embodiments, parameter adjustments may be determined (e.g., an amount a given parameter should be changed), and the parameters may be adjusted from prior parameter set points to new parameter set points, for example.

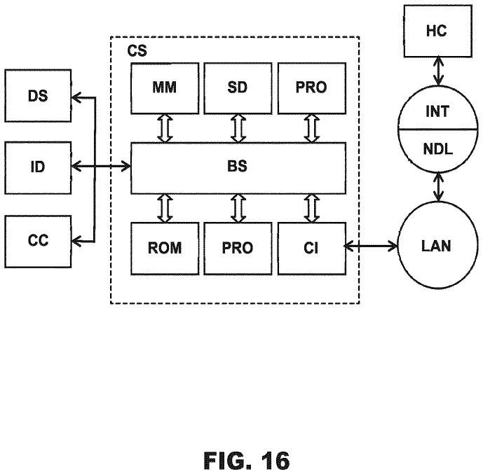

FIG. 16 is a diagram of an example computer system CS (which may be similar to or the same as CS shown in FIG. 3) that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have (machine-readable) instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more machine-readable instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

By way of an example, for an SEM (e.g., as described above), a computer readable medium may be provided that stores instructions for a processor (PRO) of a controller (e.g., CS) to carry out image inspection, image acquisition, activating a charged-particle source, adjusting electrical excitation of stigmators, adjusting landing energy of electrons, adjusting objective lens excitation, adjusting secondary electron detector position and orientation, stage motion control, beam separator excitation, applying scan deflection voltages to beam deflectors, receiving and processing data associated with signal information from electron detectors, configuring an electrostatic element, detecting signal electrons, adjusting the control electrode potential, adjusting the voltages applied to the electron source, extractor electrode, and the sample, etc.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, or stored in storage device SD, or other non-volatile storage for later execution. In this manner, computer system CS may obtain application code in the form of a carrier wave.

The concepts disclosed herein may be used with any imaging, etching, polishing, inspection, etc. system for sub wavelength features, and may be useful with emerging imaging technologies capable of producing increasingly shorter wavelengths. Emerging technologies include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range. Embodiments of the present disclosure can be further described by the following clauses.

1. A method for selecting one or more subsets of fields of view of a pattern layout, the method comprising:
determining a set of candidate fields of view based on pattern groups of the pattern layout; and
selecting the one or more subsets of the fields of view from the set of candidate fields of view according to prescribed criteria and based on the pattern groups, wherein the prescribed criteria is for combinations of fields of view included in the one or more subsets for scanning electron microscope (SEM) measurement.

2. The method of clause 1, further comprising grouping patterns of the pattern layout into the pattern groups, the grouping comprising pattern matching to produce the pattern groups.

3. The method of clause 1 or 2, wherein each of the one or more subsets corresponds to a field of view list.

4. The method of any of clauses 1-3, wherein a field of view includes a portion of the pattern layout.

5. The method of any of clauses 1-4, wherein a subset of fields of view comprises a list of fields of view selected from the set of candidate fields of view.

6. The method of any of clauses 1-5, wherein selecting the one or more subsets comprises assigning fields of view including specific patterns to respective fields of view lists by applying a graph based overlapping elimination algorithm.

7. The method of clause 6, wherein the graph based overlapping elimination algorithm comprises a graph coloring algorithm, and wherein each field of view list corresponds to a color.

8. The method of clause 6 or 7, wherein the graph based elimination and/or graph coloring algorithm outputs a diverse group of patterns in a predetermined number of lists of fields of view based on the prescribed criteria.

9. The method of any of clauses 1-5, wherein selecting the one or more subsets comprises assigning fields of view including specific patterns to respective fields of view lists by applying an integer linear programming algorithm.

10. The method of clause 9, wherein selecting the one or more subsets comprises assigning fields of view including specific patterns to respective fields of view lists by applying the integer linear programming algorithm and a graph coloring algorithm, wherein each field of view list corresponds to a color.

11. The method of clause 9 or 10, wherein the prescribed criteria is configured such that the integer linear programming and/or graph coloring algorithm outputs an optimally diverse group of patterns in a predetermined number of lists of fields of view.

12. The method of any of clauses 1-11, wherein determining the set of candidate fields of view is further based constraints on characteristics of a given field of view.

13. The method of clause 12, wherein the characteristics of a given field of view comprise a distance from the given field of view to another field of view and/or a size of the given field of view.

14. The method of any of clauses 1-13, wherein determining the set of candidate fields of view is further based on a generation method comprising matched instance pattern replacement for the set of candidate fields of view.

15. The method of clause 14, wherein the matched instance pattern replacement comprises pattern matching of patterns in the pattern layout to produce pattern groups, and selecting an alternate pattern from the same pattern group to replace a pattern in the pattern group.

16. The method of any of clauses 1-15, wherein determining the set of candidate fields of view is based on a generation method comprising field of view merging and/or shifting.

17. The method of clause 16, wherein field of view merging and/or shifting comprises combining patterns from different pattern groups into a single candidate field of view.

18. The method of clause 16 or 17, wherein field of view merging and/or shifting is based on a proximity of patterns from different pattern groups to each other.

19. The method of any of clauses 1-18, wherein the prescribed criteria comprises a pattern group diversity metric.

20. The method of any of clauses 1-19, wherein the prescribed criteria comprises a pattern group criticality metric.

21. The method of clause 20, wherein the pattern group criticality metric comprises a weight of a pattern group.

22. The method of any of clauses 1-21, wherein the prescribed criteria comprises a subset and/or fields of view quantity metric.

23. The method of any of clauses 1-22, wherein determining the set of candidate fields of view based on pattern groups of the pattern layout comprises determining the set of candidate fields of view based on a list of pattern locations and matching information for the pattern groups.

24. The method of any of clauses 1-23, wherein the prescribed criteria is set such that patterns included in the one or more subsets of fields of view in combination represent an entirety of the pattern layout or a portion of the pattern layout.

25. The method of any of clauses 1-24, wherein the prescribed criteria causes inclusion of an optimally diverse group of patterns in a predetermined number of subsets of fields of view.

26. The method of clause 25, wherein the optimally diverse group of patterns comprises a plurality of patterns having geometries that, in combination, represent at least a threshold amount of the pattern layout, given the predetermined number of subsets that form the determined one or more subsets.

27. The method of clause 25 or 26, wherein the predetermined number of subsets is set by a user.

28. The method of any of clauses 25-27, wherein the predetermined number of subsets is minimized.

29. The method of any of clauses 1-28, further comprising providing the determined one or more subsets of fields of view as input for model calibration, critical dimension (CD) metrology, and/or defect inspection for a semiconductor lithography process.

30. The method of any of clauses 1-29, wherein the pattern layout comprises a design layout for a semiconductor wafer.

31. The method of any of clauses 1-30, wherein selecting the one or more subsets comprises assigning fields of view including specific patterns to respective fields of view lists by applying an integer linear programming algorithm, wherein the criteria is defined as constraint cliques.

32. A non-transitory computer readable medium having instructions thereon, the instructions when executed by a computer causing the computer to perform the method of any of clauses 1-30.

33. A system for selecting one or more subsets of fields of view of a pattern layout, the system comprising one or more processors configured by machine readable instructions to perform the method of any of clauses 1-30.

34. A non-transitory computer readable medium having instructions thereon, the instructions when executed by a computer causing the computer to perform a method for selecting one or more lists of fields of view of a pattern layout, the method comprising:
determining a set of candidate fields of view based on pattern groups of the pattern layout and constraints on characteristics of a given field of view, wherein the characteristics of a given field of view comprise a distance from the given field of view to another field of view and/or a size of the given field of view; and
selecting the one or more lists of the fields of view from the set of candidate fields of view according to prescribed criteria for combinations of fields of view included in the one or more lists for scanning electron microscope measurement, wherein selecting the one or more lists comprises: assigning fields of view including specific patterns to respective lists by applying a graph based elimination and graph coloring algorithm, wherein each field of view list corresponds to a color; or assigning fields of view including specific patterns to respective fields of view lists by applying an integer linear programming algorithm and graph coloring algorithm, wherein each field of view corresponds to a color;
wherein the prescribed criteria comprises inclusion of an optimally diverse group of patterns in a predetermined number of lists of fields of view.

35. The medium of clause 34, wherein determining the set of candidate fields of view is further based on a generation method for the set of candidate fields of view comprising matched instance seed pattern replacement and/or field of view merging and/or shifting.

36. The medium of clause 34, wherein the prescribed criteria comprises a pattern group diversity metric, a pattern group weight, and/or a list and/or field of view quantity metric.

37. The medium of clause 34, wherein the optimally diverse group of patterns comprises a plurality of patterns having geometries that, in combination, represent at least a threshold amount of the pattern layout, given a number of lists in the determined one or more lists.

38. The medium of clause 34, the method further comprising providing the one or more lists of fields of view as input for model calibration, critical dimension (CD) metrology, and/or defect inspection for a semiconductor lithography process.

While the concepts disclosed herein may be used for manufacturing with a substrate such as a silicon wafer, it shall be understood that the disclosed concepts may be used with any type of manufacturing system (e.g., those used for manufacturing on substrates other than silicon wafers).

In addition, the combination and sub-combinations of disclosed elements may comprise separate embodiments. For example, one or more of the operations described above may be included in separate embodiments, or they may be included together in the same embodiment.

The descriptions above are intended to be illustrative, not limiting. Thus, it will be apparent to one skilled in the art that modifications may be made as described without departing from the scope of the claims set out below.

1. A method for selecting one or more subsets of fields of view of a pattern layout, the method comprising:
determining, by a hardware computer system, a set of candidate fields of view based on pattern groups of the pattern layout; and
selecting the one or more subsets of the fields of view from the set of candidate fields of view according to prescribed criteria and based on the pattern groups, wherein the prescribed criteria is for combinations of fields of view included in the one or more subsets for scanning electron microscope (SEM) measurement.

2. The method of claim 1, further comprising grouping patterns of the pattern layout into the pattern groups, the grouping comprising pattern matching to produce the pattern groups.

3. The method of claim 1, wherein each of the one or more subsets corresponds to a field of view list.

4. The method claim 1, wherein a subset of fields of view comprises a list of fields of view selected from the set of candidate fields of view.

5. The method of claim 1, wherein selecting the one or more subsets comprises assigning fields of view including specific patterns to respective fields of view lists by applying a graph based overlapping elimination algorithm.

6. The method of claim 5, wherein the graph based overlapping elimination algorithm comprises a graph coloring algorithm, and wherein each field of view list corresponds to a color.

7. The method of claim 1, wherein selecting the one or more subsets comprises assigning fields of view including specific patterns to respective fields of view lists by applying an integer linear programming algorithm to determine an optimally diverse group of patterns in a predetermined number of lists of fields of view, wherein the prescribed criteria is defined as constraint cliques.

8. The method of claim 1, wherein determining the set of candidate fields of view is further based on a constraint on a characteristic of a given field of view, wherein the characteristic of a given field of view comprises a distance from the given field of view to another field of view and/or a size of the given field of view.

9. The method of claim 1, wherein determining the set of candidate fields of view is further based on a generation method comprising matched instance pattern replacement for the set of candidate fields of view.

10. The method of claim 9, wherein the matched instance pattern replacement comprises pattern matching of patterns in the pattern layout to produce pattern groups, and selecting an alternate pattern from the same pattern group to replace a pattern in the pattern group.

11. The method of claim 1, wherein determining the set of candidate fields of view is based on a generation method comprising field of view merging and/or shifting, wherein field of view merging and/or shifting comprises combining patterns from different pattern groups into a single candidate field of view.

12. The method of claim 11, wherein field of view merging and/or shifting is based on a proximity of patterns from different pattern groups to each other.

13. The method of claim 1, wherein the prescribed criteria comprises a pattern group diversity metric or a pattern group criticality metric, wherein the pattern group criticality metric comprises a weight of a pattern group.

14. The method of claim 1, wherein determining the set of candidate fields of view based on pattern groups of the pattern layout comprises determining the set of candidate fields of view based on a list of pattern locations and matching information for the pattern groups.

15. The method of claim 1, wherein the prescribed criteria causes inclusion of an optimally diverse group of patterns in a predetermined number of subsets of fields of view.

16. A non-transitory computer readable medium having instructions thereon or therein, the instructions, when executed by a computer system, configured to cause the computer system to at least:
determine a set of candidate fields of view based on pattern groups of a pattern layout; and
selecting one or more subsets of fields of view of the pattern layout from the set of candidate fields of view according to prescribed criteria and based on the pattern groups, wherein the prescribed criteria is for combinations of fields of view included in the one or more subsets for scanning electron microscope (SEM) measurement.

17. The medium of claim 16, wherein the instructions are further configured to cause the computer system to group patterns of the pattern layout into the pattern groups, the grouping comprising pattern matching to produce the pattern groups.

18. The medium of claim 16, wherein each of the one or more subsets corresponds to a field of view list.

19. The medium of claim 16, wherein selection of the one or more subsets comprises assignment of fields of view including specific patterns to respective fields of view lists by application of a graph based overlapping elimination algorithm or by application of an integer linear programming algorithm to determine an optimally diverse group of patterns in a predetermined number of lists of fields of view.

20. A non-transitory computer readable medium having instructions thereon or therein, the instructions, when executed by a computer system, configured to cause the computer system to at least:
determine a set of candidate fields of view based on pattern groups of a pattern layout and a constraint on a characteristic of a given field of view, wherein the characteristic of a given field of view comprise a distance from the given field of view to another field of view and/or a size of the given field of view; and
select one or more lists of fields of view for the pattern layout from the set of candidate fields of view according to prescribed criteria for combinations of fields of view included in the one or more lists for scanning electron microscope measurement, wherein the selection of the one or more lists comprises:
assignment of fields of view including specific patterns to respective lists by application of a graph based elimination and graph coloring algorithm, wherein each list corresponds to a color; or
assignment of fields of view including specific patterns to respective lists by application of an integer linear programming algorithm and graph coloring algorithm, wherein each field of view corresponds to a color,
wherein the prescribed criteria comprises inclusion of an optimally diverse group of patterns in a predetermined number of lists of fields of view.
